(19) United States
(12) Patent Application Publication
(10) Pub. No.: US 2015/0173203 A1
(43) Pub. Date: Jun. 18, 2015

(54) THREE-DIMENSIONAL PRINTING APPARATUS

(71) Applicants: XYZprinting, Inc., New Taipei City (TW); Cal-Comp Electronics & Communications Company Limited, New Taipei City (TW); Kinpo Electronics, Inc., New Taipei City (TW)

(72) Inventor: Shih-Jer Din, New Taipei City (TW)

(73) Assignees: XYZprinting, Inc., New Taipei City (TW); Cal-Comp Electronics & Communications Company Limited, New Taipei City (TW); Kinpo Electronics, Inc., New Taipei City (TW)

(21) Appl. No.: 14/160,569

(22) Filed: Jan. 22, 2014

(30) Foreign Application Priority Data
Dec. 12, 2013 (TW) 102145916

(51) Int. Cl. H05K 3/10; B29C 67/00

(52) U.S. Cl. CPC H05K 3/108; B29C 67/0059; B29C 67/0088; B29C 67/0085

(57) ABSTRACT

A three dimensional printing apparatus used for printing a printed circuit board (PCB) in melting manner is provided. The three dimensional printing apparatus includes a platform, a first printing unit, a second printing unit, a third printing unit, and a control unit. The first printing unit supplies a meltable insulation material, the second printing unit supplies a meltable conductive material, and the third printing unit supplies a meltable adhesive material. The control unit is electrically connected to the first printing unit, the second printing unit and the third printing unit, wherein the first printing unit is driven by the control unit to generate an insulation layer, the second printing unit is driven by the control unit to generate a conductive layer, and the third printing unit is driven by the control unit to generate an adhesion layer between the conductive layer and the insulation layer to form the PCB.

### CROSS-REFERENCE TO RELATED APPLICATION

This application claims the priority benefit of Taiwan application serial no. 102145916, filed on Dec. 12, 2013. The entirety of the above-mentioned patent application is hereby incorporated by reference herein and made a part of this specification.

### BACKGROUND

1. Technical Field

The invention relates to a printing apparatus. Particularly, the invention relates to a three-dimensional printing apparatus for printing a circuit board.

2. Related Art

Along with progress of computer-aided manufacturing (CAM), three-dimensional (3D) printing technology is developed to rapidly convert original design concept into physical models.

The 3D printing technology is actually a general designation of a series of rapid prototyping (RP) techniques, and a basic principle thereof is additive manufacturing, where a RP machine is used to form sectional shapes of a workpiece in an X-Y plane through scanning, and intermittently shift by a layer thickness along a Z-axis, so as to form a 3D object. The 3D printing technology is not limited to any geometric shape, and the more complex the workpiece is, the more excellence the RP technology is demonstrated. The 3D printing technology can greatly save manpower and processing time, and under a demand of the shortest time, digital 3D model information designed by software of 3D computer-aided design (CAD) can be truly presented as a physical part, which is not only touchable, a user can also actually feel a geometric curve of the physical part, and can test assemblability of the physical part, or even perform possible functional tests.

### SUMMARY

The exemplary embodiment is directed to a three-dimensional printing apparatus for printing a printed circuit board in a three-dimensional manner.

The exemplary embodiment provides a three-dimensional printing apparatus used for printing a printed circuit board in a melting manner. The three-dimensional printing apparatus includes a platform, a first printing unit, a second printing unit, a third printing unit, and a control unit. The first printing unit supplies a meltable insulation material, the second printing unit supplies a meltable conductive material, and the third printing unit supplies a meltable adhesive material. The control unit is electrically connected to the first printing unit, the second printing unit and the third printing unit. The control unit sequentially controls the first printing unit and the second printing unit to print an insulation layer and a conductive layer on the platform in a three-dimensional manner, and controls the third printing unit to coat the meltable adhesive material between the insulation layer and the conductive layer to form the printed circuit board.

In an exemplary embodiment, the three-dimensional printing apparatus is a fused deposition modeling (FDM) three-dimensional printing apparatus.

In an exemplary embodiment, the three-dimensional printing apparatus further includes a moving unit disposed above the platform and electrically connected to the control unit, where the first printing unit, the second printing unit and the third printing unit are disposed on the moving unit.

In an exemplary embodiment, the first printing unit has a first heater, and the second printing unit has a second heater for heating and melting the meltable insulation material and the meltable conductive material.

In an exemplary embodiment, the third printing unit has a third heater for heating and melting the meltable adhesive material.

According to the above exemplary embodiments, different printing units of the three-dimensional printing apparatus are used to print the printed circuit board, where the first printing unit supplies the meltable insulation material, the second printing unit supplies the meltable conductive material, and the third printing unit supplies the meltable adhesive material, so as to print the printed circuit board on the platform in a three-dimensional manner according to a three-dimensional printing method. In this way, by using the insulation layer and the conductive layer formed layer-by-layer and the meltable adhesive material coated between the insulation layer and the conductive layer, the insulation layer and the conductive layer are adhered to form the printed circuit board. In this way, the printed circuit board and a circuit pattern thereon are rapidly printed, so as to improve a sample manufacturing efficiency to expand an application level of the three-dimensional printing apparatus and promote industrial competitiveness.

In order to make the aforementioned and other features and advantages comprehensible, several exemplary embodiments accompanied with figures are described in detail below.

### BRIEF DESCRIPTION OF THE DRAWINGS

The accompanying drawings are included to provide a further understanding of the exemplary embodiments, and are incorporated in and constitute a part of this specification. The drawings illustrate embodiments and, together with the description, serve to explain the principles of the exemplary embodiment.

FIG. 1 is a schematic diagram of a three-dimensional (3D) printing apparatus according to an exemplary embodiment.

FIG. 2 to FIG. 4 are schematic diagrams illustrating a process that a 3D printing apparatus prints a printed circuit board.

FIG. 5 is a flowchart illustrating a 3D printing method of a printed circuit board.

### DETAILED DESCRIPTION OF DISCLOSED EMBODIMENTS

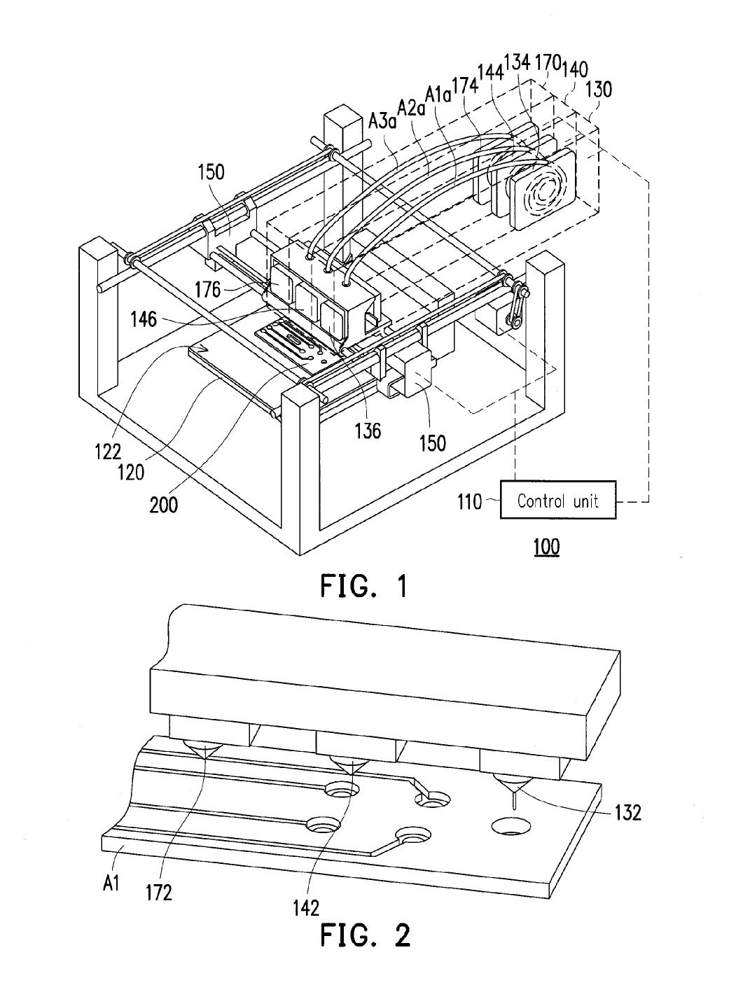

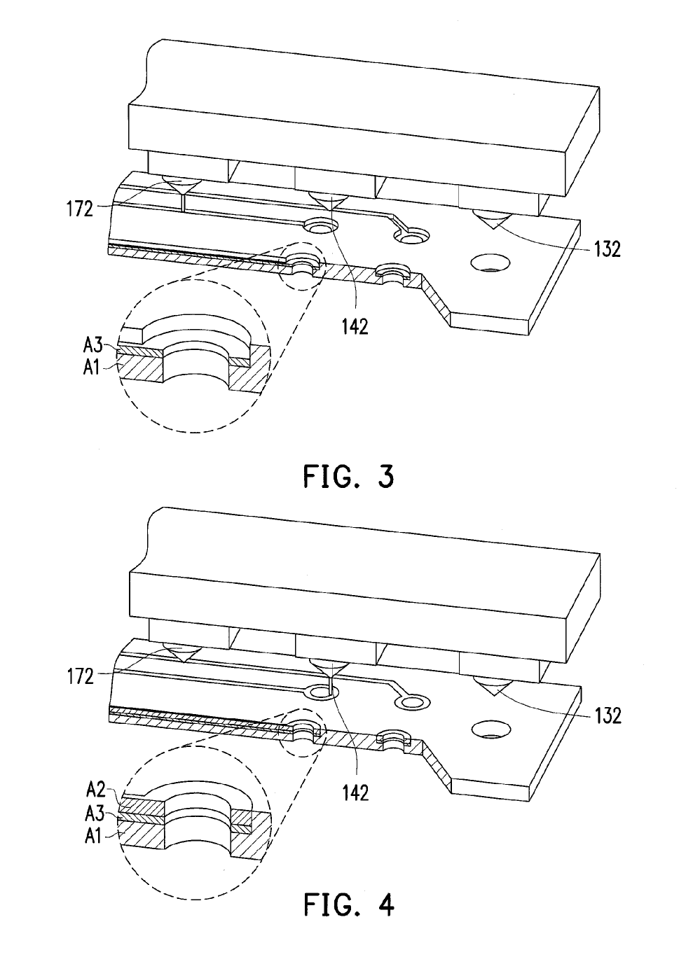

FIG. 1 is a schematic diagram of a three-dimensional (3D) printing apparatus according to an exemplary embodiment. FIG. 2 to FIG. 4 are schematic diagrams illustrating a process that the 3D printing apparatus prints a printed circuit board. Referring to FIG. 1 to FIG. 4, in the present embodiment, the 3D printing apparatus 100 is, for example, a fused deposition modeling (FDM) 3D printing apparatus, which is adapted to print a 3D object according to digital 3D model information. In the present embodiment, the 3D object is a printed circuit board 200 including an insulating plate and a pattern circuit thereon, which is described in detail later.

In the present embodiment, the 3D printing apparatus 100 includes a control unit 110, a platform 120, a first printing unit 130 and a second printing unit 140. The aforementioned digital 3D model information can be a digital 3D image file, which is, for example, constructed by a computer through computer-aided design (CAD) or by using animation modeling software, etc. The control unit 110 can be used to read and process the digital 3D model information.

The platform 120 has a carrying surface 122 for carrying a meltable material sprayed by the first printing unit 130 and the second printing unit 140. In the present embodiment, the first printing unit 130 and the second printing unit 140 respectively include a printing head 132, 142 and a material feeding tray 134, 144 connected to each other. Further, the material feeding tray 134 of the first printing unit 130 contains a meltable insulation material Ala for supplying to the printing head 132, and the material feeding tray 144 of the second printing unit 140 contains a meltable conductive material A2a for supplying to the printing head 142.

Moreover, the 3D printing apparatus 100 further includes a moving unit 150 electrically connected to the control unit 110, where the printing head 132 of the first printing unit 130 and the printing head 142 of the second printing unit 140 are respectively disposed on the moving unit 150 and move above the platform 150 along with the moving unit 150 under control of the control unit 110. Here, the moving unit 150 is, for example, an X-Y planar moving rack used for driving the printing heads 132 and 142 to move above and in parallel to the platform 120. In another embodiment that is not illustrated, the moving unit 150 can also be an X-Y-Z three-dimensional moving rack, such that besides the aforementioned movements, the printing heads can also move up and down to approach to or depart from the platform 120.

The first printing unit 130 further has a first heater 136, and the second printing unit 140 further has a second heater 146. Further, the first heater 136 and the second heater 146 are respectively used for heating the meltable insulation material A1 a and the meltable conductive material A2a in the printing heads 134 and 144, such that the meltable insulation material Ala and the meltable conductive material A2a are melted and printed on the platform 120 layer-by-layer through the controlled printing heads 132 and 142 to form the 3D object (i.e. the printed circuit board 200). In other words, the meltable insulation material Ala and the meltable conductive material A2a are respectively solid state wires composed of meltable materials, and the first heater 136 and the second heater 146 can be used to heat the solid state wires, and the meltable material presents a melting state, and is squeezed out of the printing heads 132 and 142 to stack on the carrying surface 122 layer-by-layer from bottom to top, so as to form a plurality of meltable material layers, and the melt material layers are stacked to form the printed circuit board 200.

On the other hand, in order to smoothly bond the meltable insulation material A1a and the meltable conductive material A2a, the 3D printing apparatus 100 of the present embodiment further includes a third printing unit 170 electrically connected to the control unit 110. Similar to the first printing unit 130 and the second printing unit 140, the third printing unit 170 includes a printing head 172, a material feeding tray 174 and a third heater 176 connected to each other, where the material feeding tray 174 contains a meltable adhesive material A3a of the solid state wire, which is also heated and melted by the third heater 160, and the printing head 172 is controlled to spray the meltable adhesive material A3a onto the platform 120. Further, after the meltable insulation material A1a is sprayed onto the platform 120 by the first printing unit 130 and is cured to form the insulation layer A1, the control unit 110 further drives the third printing unit 170 to spray the meltable adhesive material A3a to the insulation layer A3 to form an adhesion layer A3, and then the control unit 110 drives the second printing unit 140 to spray a conductive layer A2 on the adhesion layer A3. In this way, by controlling a melting and spraying timing of the meltable insulation material Ala, the meltable conductive material A2a and the meltable adhesive material A3a, and filling the meltable adhesive material A3a between the meltable insulation material A1a and the meltable conductive material A2a to serve as a medium used for connecting the meltable insulation material A1a and the meltable conductive material A2a, a connection strength of the insulation layer A1 and the conductive layer A2 is enhanced and a structure strength of the printed circuit board 200 is strengthened.

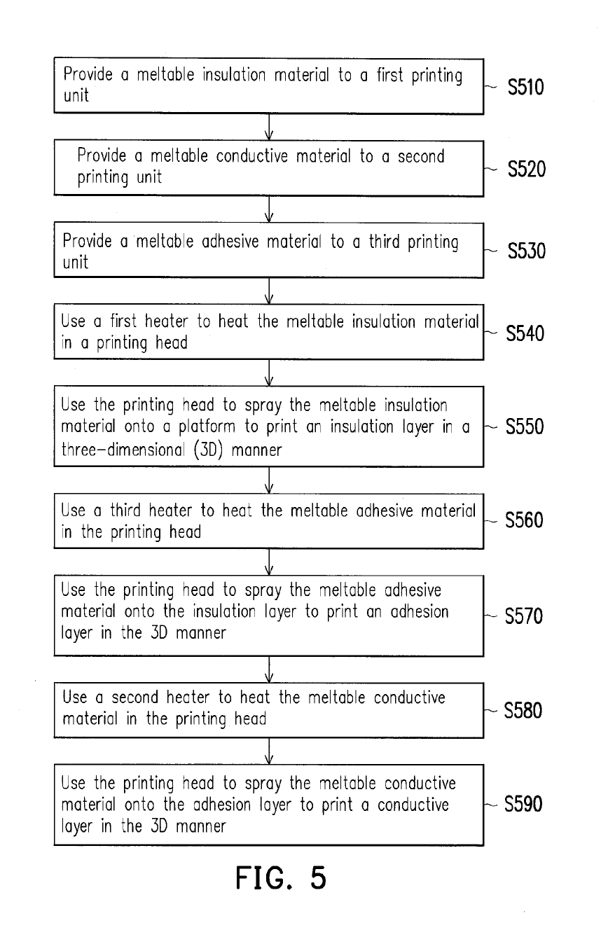

FIG. 5 is a flowchart illustrating a 3D printing method of a printed circuit board. Referring to FIG. 5 and FIG. 2 to FIG. 4, in the present embodiment, in step S510-S530, the meltable insulation material A1a is provided to the first printing unit 130, the meltable conductive material A2a is provided to the second printing unit 140, and the meltable adhesive material A3a is provided to the third printing unit 170. In other words, as shown in FIG. 1, the above steps can be implemented by connecting the material feeding trays 134, 144 and 174 containing the solid state wires to the printing heads 132, 142 and 172. Certainly, when the above materials are used out or required to be replaced, it can be resolved by only replacing the material feeding trays 134, 144 and 174.

Then, in steps S540 and S550, the first heater 136 heats the meltable insulation material A1a in the printing head 132, and the meltable insulation material A1a is sprayed on the platform 120 to print the insulation layer A1 in the 3D manner, where after the insulation layer A1 is cured, a plurality of openings or grooves are formed at predetermined positions of the circuit pattern, as that shown in FIG. 2. Then, in step S560 and S570, the third heater 176 is used to heat the meltable adhesive material A3a in the printing head 172, and the meltable adhesive material A3a is sprayed on the insulation layer A1 to print the adhesion layer A3 in the 3D manner, i.e.

the meltable adhesive material A3a is sprayed into the aforementioned openings or grooves to form the adhesion layer A3. Finally, in step S580 and S590, the second heater 146 is used to heat the meltable conductive material A2a in the printing head 144, and the meltable conductive material A2a is sprayed on the adhesion layer A3, i.e. the meltable conductive material A2a is filled in the aforementioned openings or grooves to form the conductive layer A2. In this way, the adhesion layer A3 adheres the insulation layer A1 and the conductive layer A2 to form the printed circuit board 200.

In summary, in the aforementioned exemplary embodiments, different printing units of the three-dimensional printing apparatus are used to print the printed circuit board, where the first printing unit supplies the meltable insulation material, the second printing unit supplies the meltable conductive material, and the third printing unit supplies the meltable adhesive material, so as to print the printed circuit board on the platform in a three-dimensional manner according to a three-dimensional printing method. In this way, by using the circuit board structure composed of the insulation layer and the conductive layer formed layer-by-layer, the printed circuit board and the circuit pattern thereon can be quickly printed.

Moreover, after the insulation layer is cured and before the conductive layer is coated, by spraying the meltable adhesive material, the subsequent conductive layer can be suitably bonded to the insulation layer after being cured, so as to enhance a bonding degree of the insulating layer and the conductive layer and strengthen a structure strength of the printed circuit board. In this way, the printed circuit board fabricated by the 3D printing apparatus according to the 3D printing method of the exemplary embodiments may have improved manufacturing efficiency, so as to expand an application level of the three-dimensional printing apparatus and promote industrial competitiveness thereof.

It will be apparent to those skilled in the art that various modifications and variations can be made to the structure of the exemplary embodiments without departing from the scope or spirit thereof. In view of the foregoing, it is intended that the exemplary embodiments cover modifications and variations of the exemplary embodiments provided they fall within the scope of the following claims and their equivalents.

What is claimed is:

1. A three-dimensional printing apparatus, configured to print a printed circuit board in a melting manner, the three-dimensional printing apparatus comprising:
a platform;
a first printing unit, supplying a meltable insulation material;
a second printing unit, supplying a meltable conductive material;
a third printing unit, supplying a meltable adhesive material; and
a control unit, electrically connected to the first printing unit, the second printing unit and the third printing unit, wherein the control unit sequentially controls the first printing unit and the second printing unit to respectively spray the meltable insulation material and the meltable conductive material onto the platform to form an insulation layer and a conductive layer, and controls the third printing unit to coat the meltable adhesive material between the insulation layer and the conductive layer to form the printed circuit board.

2. The three-dimensional printing apparatus as claimed in claim 1, wherein the three-dimensional printing apparatus is a fused deposition modeling (FDM) three-dimensional printing apparatus.

3. The three-dimensional printing apparatus as claimed in claim 1, further comprising:
a moving unit, disposed above the platform and electrically connected to the control unit, wherein the first printing unit, the second printing unit and the third printing unit are disposed on the moving unit.

4. The three-dimensional printing apparatus as claimed in claim 1, wherein the first printing unit has a first heater, and the second printing unit has a second heater for heating and melting the meltable insulation material and the meltable conductive material.

5. The three-dimensional printing apparatus as claimed in claim 1, wherein the third printing unit has a third heater for heating and melting the meltable adhesive material.
